(19) United States
(12) Patent Application Publication
(10) Pub. No.: US 2008/0061338 A1
(43) Pub. Date: Mar. 13, 2008

(54) Method for Processing a Structure of a Semiconductor Component, and Structure in a Semiconductor Component

(76) Inventors: Ludovic Lattard, Dresden (DE); Christoph Noelscher, Nuernberg (DE); Martin Verhoeven, Eindhoven (NL)

Correspondence Address: SLATER & MATSIL, L.L.P., 17950 PRESTON ROAD, SUITE 1000, DALLAS, TX, 75252, US

(21) Appl. No.: 11/851,162

(22) Filed: Sep. 6, 2007

(30) Foreign Application Priority Data
Sep. 7, 2006 (DE) 10 2006 043 113.8

(51) Int. Cl. H01L 27/108; H01L 21/311

(52) U.S. Cl. 257/296; 257/618; 438/703; 257/E29.084; 257/E21.249

(57) ABSTRACT

A method is used for processing a structure of a semiconductor component. The structure has at least one partial structure to be etched, in particular a sublithographic partial structure. The at least one partial structure has at least one structure to be etched with at least one lateral etch stop to which at least one mask is applied in such a way that at least one lateral etch stop is covered by the mask and afterward at least one of the structures to be etched is etched away isotropically as far as at least one etch stop using the mask. The at least one mask and the at least one etch stop are then removed.

This application claims priority to German Patent Application 10 2006 043 113.8, which was filed Sep. 7, 2006 and is incorporated herein by reference.

### TECHNICAL FIELD

An embodiment of the invention relates to a method for processing a structure of a semiconductor component and to a structure of a semiconductor component.

### BACKGROUND

The production of ever smaller structures is a constant challenge in the production of semiconductor components, such as, e.g., DRAM chips or NROM chips.

The resolution of the lithographic methods is inherently limited by the wavelengths of the exposure source, the properties of the mask and of the optical system. Wavelengths (λ) of 248 nm and 193 nm are used at the present time. Exposure sources for shorter wavelengths such as 157 nm or extreme ultraviolet (EUV) sources at 13 nm are being developed. Structures having a CD (critical dimension) that is less than the exposure wavelength are referred to as subwavelength structures.

Through various methods it is possible to attain the theoretical resolution limit in the production of structures on a substrate. By using special masks, such as, e.g., phase shifter masks or binary masks with dipole exposure sources, it is possible to attain a minimum half-pitch in line structures of 0.25*λ/NA (where NA is the numerical aperture of the exposure system).

Structures on a half-pitch of less than 0.25*λ/NA or less than the minimum half-pitch that can be achieved in practice by means of the exposure tool are referred to as sublithographic structures since these have to be produced by means of non-lithographic method steps, such as, e.g., etching and/or deposition.

Examples of sublithographic techniques which can be used to produce e.g. regular array structures are described in DE 42 35 702 A1 and DE 42 36 609 A1, and also US 2006 0024621A1 and DE 10 2004 034572A1. DE 42 36 609 A1 describes a so-called line-by-spacer method which can be used to produce sublithographic spacers.

Generally, in the production of semiconductor components there is a problem that specific parts have to be removed from a desired pattern, e.g., a regular line array or a two-dimensional pad pattern, e.g., a regular two-dimensional array, which is difficult particularly when parts of the structure to be removed are sublithographic.

### SUMMARY OF THE INVENTION

In one aspect, the present invention provides a method and a structure enabling targeted removal of a portion of a structure in an efficient manner.

According to an embodiment of the invention, the following steps are carried out, wherein the wafer is imagined to be horizontal (without any restriction of generality) and a positive resist is employed. A partial structure has at least one structure to be etched and at least one lateral etching stop. At least one mask is applied to the partial structure in such a way that at least one lateral etching stop is covered (darkened) by the mask. Afterward at least one of the structures to be etched is etched away isotropically as far as the at least one etching stop using the mask, and afterward a removal of the at least one mask and removal of the at least one etching stop are effected.

As a result of the targeted covering of the lateral etching stop, specific parts of a structure can be removed efficiently and precisely by means of an isotropic etching. Particularly when sublithographic etching stops are used, it is possible to determine very precisely that part which is intended to be etched away. Particularly in the case of lateral dimensions of the etching stop smaller than the edge position tolerance, no other method is possible for exact patterning.

### BRIEF DESCRIPTION OF THE DRAWINGS

The invention is explained in more detail below on the basis of a plurality of exemplary embodiments with reference to the figures of the drawings, in which:

FIG. 1 shows a schematic sectional view of an array structure with a mask for representing the production problems in accordance with the prior art;

FIG. 2 shows a schematic sectional view of an array structure with a first line structure;

FIG. 3 shows a schematic sectional view of the first line structure according to FIG. 3 with a liner layer;

FIG. 4 shows a schematic sectional view of the first line structure with a horizontal spacer structure etched on the liner;

FIG. 5 shows a schematic sectional view of the first line structure of a filled second line structure;

FIG. 6 shows a schematic sectional view of the array structure from FIG. 5 after the application of a mask;

FIG. 6A shows a schematic sectional view of the layer stack in accordance with FIG. 6 with a structure at the periphery;

FIG. 7 shows a schematic sectional view of the array structure from FIG. 6 after an isotropic etching;

FIG. 7A shows a schematic sectional view of the layer stack in accordance with FIG. 7 with a structure at the periphery;

FIG. 8 shows a schematic sectional view of the array structure from FIG. 7 after the removal of the mask and of the etching stop;

FIG. 8A shows a schematic sectional view of the layer stack in accordance with FIG. 8 with a structure at the periphery;

FIG. 9A shows a schematic sectional view of a further embodiment with a two-layered mask above an array structure;

FIG. 9B shows a schematic sectional view of the embodiment in accordance with FIG. 9A with a two-layered mask above a structure at the periphery;

FIG. 10 shows a schematic sectional view of a covering of a mask over a lateral etching stop with indications with regard to the minimum covering;

FIG. 11A shows a schematic plan view of a two-dimensional pad structure with a partial structure to be removed;

FIG. 11B shows a sectional view along the line A-A in FIG. 11A;

FIG. 11C shows a sectional view in accordance with FIG. 11B after an isotropic etching;

FIG. 11D shows a plan view of the two-dimensional structure after the removal of the mask and of the spacer material;

FIG. 12A shows a plan view of a two-dimensional plug pattern with a partial structure to be removed;

FIG. 12B shows a plan view of the structure in accordance with FIG. 12A after an isotropic etching; and

FIG. 12C shows a plan view of the two-dimensional structure in accordance with FIG. 12B after the removal of the etching stops.

### DETAILED DESCRIPTION OF ILLUSTRATIVE EMBODIMENTS

FIG. 1 illustrates a sectional view through a layer stack of an array region such as occurs, e.g., in the production of a DRAM chip or an NROM chip. A GC stack 102 is applied on a silicon substrate 101, a nitride layer 103 being applied above the stack. The production of such layer stacks with the aid of patterning and deposition methods is known, in principle, and is not explained in any further detail here. Moreover, the indication of all details regarding the layer stacks hereinafter should be regarded merely by way of example.

A plurality of sublithographic line structures 104 are arranged on this layer stack 101, 102, 103, the line structures having been produced by means of one method.

Sublithographic structures are understood here to mean structures whose CD (critical dimension) are less than 0.25*λ/NA or less than the minimum half-pitch that can be achieved in practice by means of the exposure tool.

The regular line structure 104 in FIG. 1 was produced by means of a line-by-spacer filling technique, the width (pitch) of the structure (line and a spacer) here being e.g. about 65 nm.

There are regularly problems if, e.g., the line structure 104 is intended to be processed further. One example of such necessary processing is the removal of parts of the line structure 104, indicated by an arrow in FIG. 1. During the production of NROM chips it is necessary, for example, to remove two of the lines again. This removal can only be carried out with the resolution of the lithography used, which is not fine enough for the line structures 104 used.

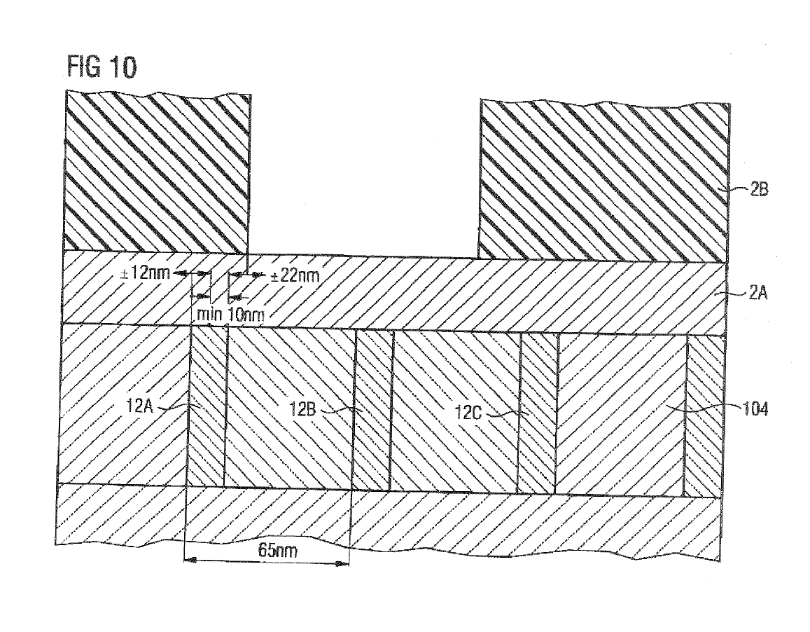

Thus, a resist 105 cannot be patterned with a precision such that it terminates precisely flush with one of the edges of the line structure 104. This resist patterning which does not have edge precision is highlighted by a circle in FIG. 1. Further possible fault sources are overlay faults and variations in the spacer width (see FIG. 10). Inaccuracies within the range of about 20 to 30 nm can occur.

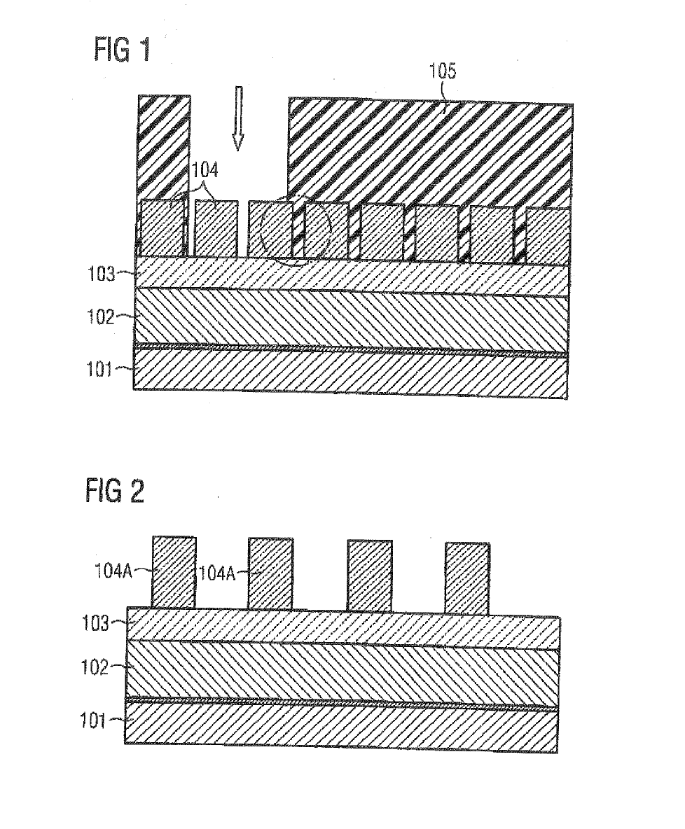

A first embodiment of a method according to the invention is described below with reference to FIGS. 2 to 8, FIGS. 2 to 5 illustrating preparatory steps that lead to the production of a starting structure (FIG. 5).

FIG. 2 illustrates a layer stack analogously to FIG. 1, such that reference is made to the description above.

By means of a customary lithography method (e.g., with a wavelength of about 248 nm), a first line structure 104A is produced on the nitride layer 103 by patterning a layer composed of amorphous silicon.

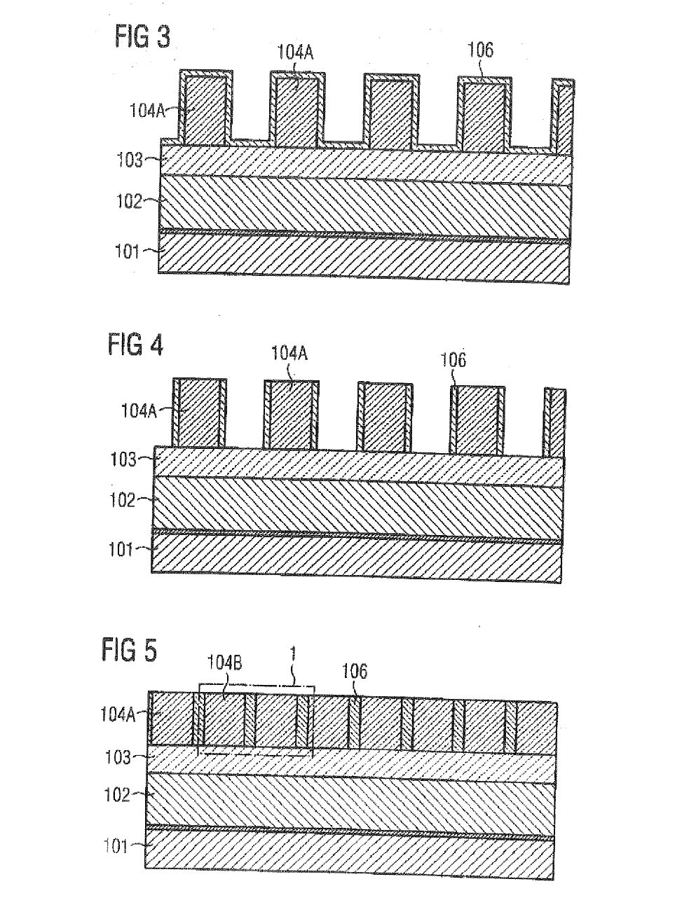

The illustration in FIG. 3 shows that a thin spacer layer 106 composed of oxide, here SiO₂, is deposited on this first line pattern 104A. The gaps between the spacer layers 106 are filled and the surface is subsequently processed as a whole, such that the horizontal parts of the spacer layer 106 are removed (e.g., by means of CMP). The filling material is subsequently removed, such that the situation in accordance with FIG. 4 is present. A first line structure 104A is in each case provided laterally with a dielectric spacer layer 106.

In a next method step, the gaps between the spacer layers 106 are filled with the same material (amorphous silicon) as the first line structure 104A. After corresponding polishing by means of CMP, the situation in FIG. 5 is present. Arranged on the nitride layer 103 is a first line structure 104A, parallel thereto a second line structure 104B, both separated from one another in each case by a thin spacer structure 106.

As an alternative, the first and second line structures 104A, 104B can comprise SiO₂, and the spacer Si₃N₄.

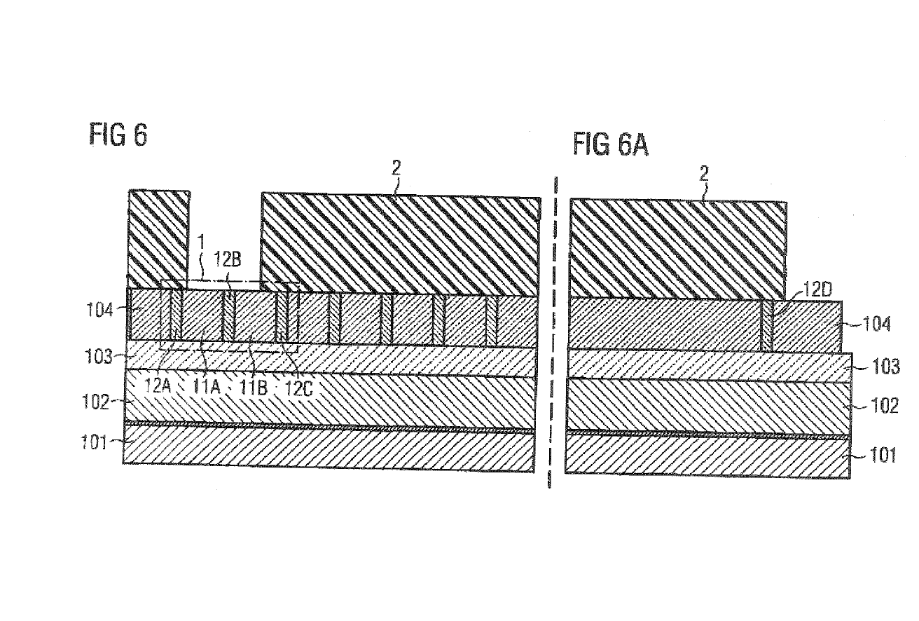

As illustrated in connection with FIG. 1, a part of the line structures 104A, 104B is then intended to be removed by an embodiment of the invention. That part of the structure which is to be processed is referred to hereinafter as sublithographic partial structure 1 and identified by a rectangle in FIG. 5 and FIG. 6.

FIGS. 6, 6A, 7, 7A, 8 and 8A in each case illustrate essentially the same layer sequence, e.g., on the same substrate 101, as in FIGS. 1 to 5. Here FIGS. 6, 7 and 8A in each case show an array region and are therefore similar to the illustrations of FIGS. 1 to 5. Array regions are identified by a large number of regular structures, such as, e.g., line structures 104 arranged parallel.

FIGS. 6A, 7A and 8A illustrate the same layer stack, only outside the array region. So-called landing pads for contact-connection are typically arranged outside the array region. FIG. 6A shows the layer structure at the periphery, that is to say in the surroundings of the regular cell array.

The first and second line structures have structures 11A, 11B to be etched within the region 1. In accordance with the embodiment of the invention that is illustrated here, the spacer layer here is in each case formed as a lateral etching stop 12A, 12B, 12C; here the etching stop is essentially formed in vertical fashion.

As illustrated in FIG. 6, a resist layer as a mask 2 is produced lithographically on this structure, and in the process it is applied in such a way that at least one lateral etching stop 12A, 12C is covered by the mask 2. An individual lateral etching stop 12D covered by the mask 2 is arranged at the periphery (FIG. 6A).

By way of example, a multilayer resist having a photoresist layer, a hard mask and/or a BARC layer can serve as mask 2.

In a next method step, the structures 11A and 11B to be etched are etched away isotropically using chlorine as far as the lateral etching stops 12A, 12B, 12C, 12D using the mask 2. It is possible to use, e.g., a CCl₄ plasma at somewhat increased pressure.

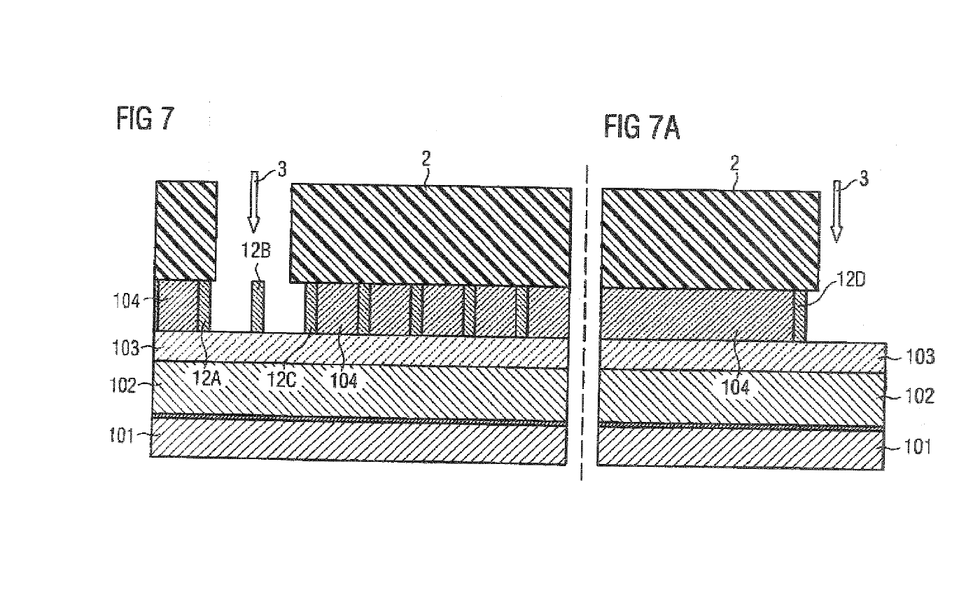

As can be discerned in FIGS. 7 and 7A, the mask 2 (that is to say the resist) is undercut. The etching stops 12A, 12C and 12D remain at least to an extent such that they can still serve as a lateral etching barrier, and the etching stop 12B can also be removed, under certain circumstances, by the attack on both sides but can also remain given selective etching; this is insignificant for the invention.

If, in an alternative embodiment, the regions 11A, 11B to be etched comprised SiO₂ and the spacer layer 106 comprised Si₃N₄, then the etching would be effected using dilute HF.

As an alternative, it is also possible firstly to carry out an anisotropic etching that does not yet lead to an undercut. Afterward, an isotropic etching can then be carried out in order to achieve the desired effect.

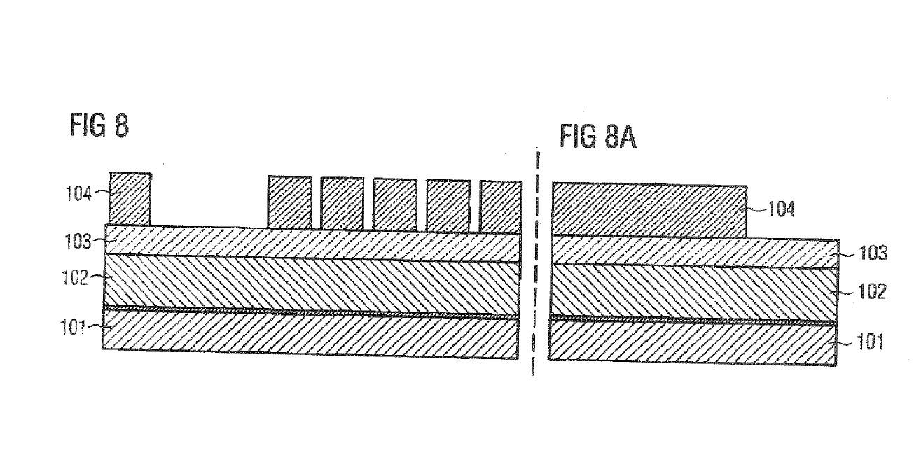

In subsequent method steps, the mask 2 and the etching stops 12A, 12B, 12C, 12D are removed by means of wet or dry etching methods known per se, such that, finally, the desired removal of the two line structures 104A, 104B is present as a result (FIG. 8).

A self-aligning removal of a structure part with a lateral etching stop 12A, 12B, 12C, 12D has thus been effected.

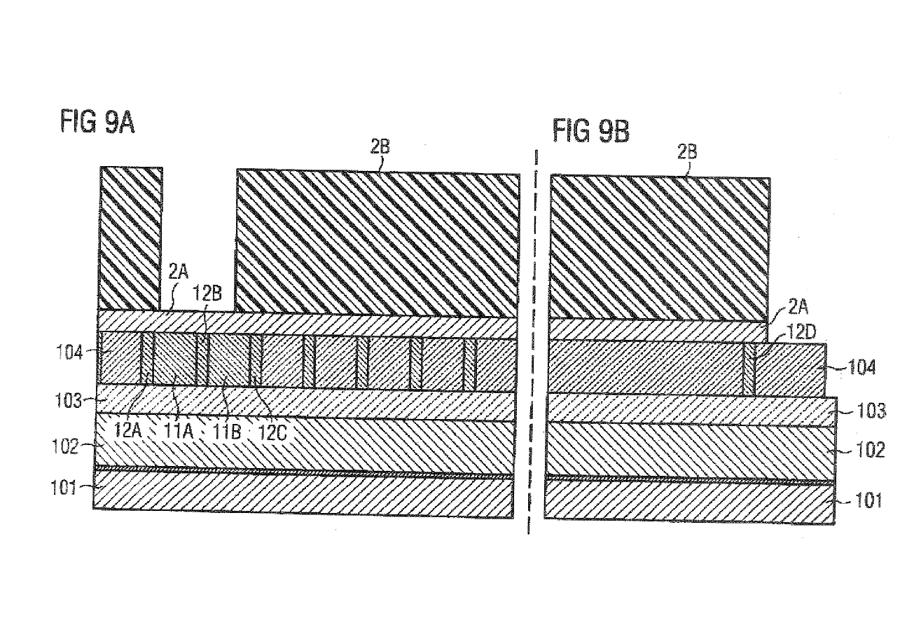

FIG. 9A illustrates essentially the same layer stack as in FIG. 6, that is to say with a mask 2 which covers two lateral etching stops (12A, 12C) in the array region. Reference can be made to the description above.

Unlike in the embodiment in accordance with FIG. 6, however, the mask 2 is formed in two layers in the embodiment in accordance with FIG. 9A. In this case, a hard mask 2A, e.g., composed of SiON, Si₃N₄ or amorphous silicon, is applied as a trimming mask on the layer to be patterned. A resist layer 2B as a trimming mask lies above it. The illustration in FIG. 9A shows that the resist layer 2B is already patterned, while the hard mask 2A is still unpatterned.

In principle, the embodiment in accordance with FIG. 6 can be understood as a follow-up form of the layer stack in accordance with FIG. 9A, that is to say that the hard mask 2A corresponds to the mask layer 2 in FIG. 6.

In this embodiment, the subsequent method steps, that is to say the isotropic etching of the line structures and the removal of the etching stops 12A, 12B, 12C, are then effected analogously to the embodiments illustrated in FIGS. 7 and 8.

FIG. 9B illustrates in the sectional view the same layer stack as in FIG. 9A, although at the periphery. Here, too, the mask 2 is in two layers. The mask 2 comprises a hard mask 2A at the bottom and an overlying resist layer 2B. The lateral etching stop 12D can be isotropically undercut after the patterning of the mask 2A, 2B.

FIG. 10 schematically illustrates what the minimally required covering of the mask 2 over a lateral etching stop 12A, 12B, 12C, 12D is required in one exemplary embodiment.

The edge precision of the resist layer structure 2B is ±22 nm. The tolerance of the edge arrangement of the lateral etching stop 12A, 12B, 12C, 12D is ±12 nm. In order to ensure a reliable covering of the mask 2, a minimum covering of 10 nm must be provided, such that an overhang still remains given a worst-case edge position of the etching stop 12A, 12B, 12C, 12D and a smallest value for the covering of the resist layer 2B.

However, the invention can be used not only in connection with sublithographic partial structures. Rather, embodiments with targeted undercutting as far as a lateral etching stop are also possible even in the case of structures having larger dimensions.

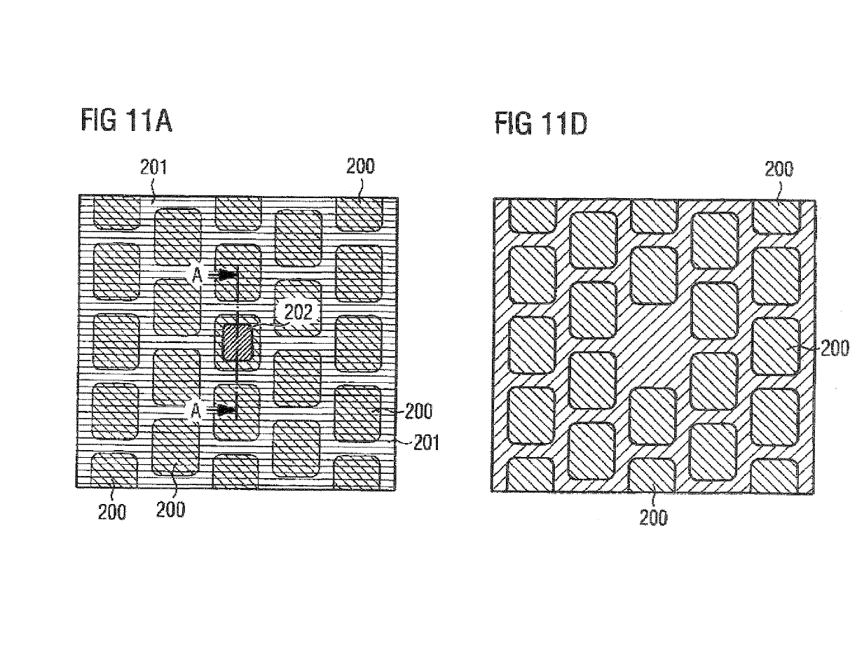

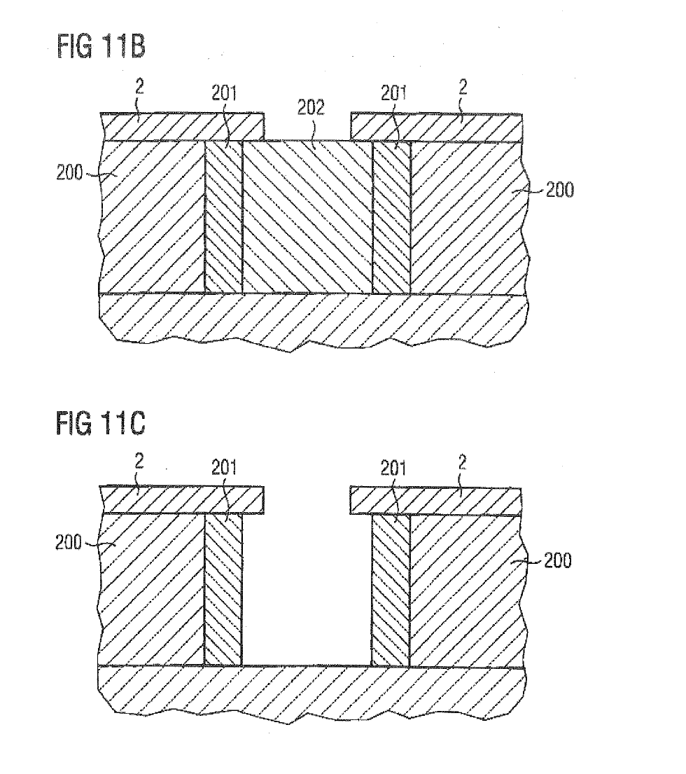

FIG. 11A illustrates a plan view of a regular two-dimensional pattern comprising pads 200. Pads can be sublithographic or non-sublithographic. A spacer material 201 is deposited between the pads 200, which spacer material can be etched selectively (analogously to the above examples or to DE 10 2004 034572 A1) with respect to the material of the pads 200. The spacer material 201 here functions as a lateral etching stop 201.

It shall be assumed in the present example that the two-dimensional pattern 200 was produced by means of a customary lithography method with a wavelength of 193 nm.

The two-dimensional pattern is almost completely covered with a mask 2, a part of a pad not being covered by the mask 2; it is this part of the two-dimensional pattern which is intended to be removed from the pattern. The pad 202 is intended to be etched away by the embodiment of the method according to the invention.

FIG. 11B illustrates a section along the line A-A in FIG. 11A, which reveals that the pad 202 to be removed is surrounded by spacer material as lateral etching stop 201. The mask 2 covers the entire pattern apart from the pad 202 to be etched, wherein the edge of this partial structure 202 to be etched is likewise covered by the mask 2. In principle, this situation corresponds to FIG. 6 of the other embodiment.

Isotropic etching results in the situation in accordance with FIG. 11C, that is to say that the mask 2 was undercut and the pad 202 to be removed has been removed since the isotropic etching was effected as far as the lateral etching stop 201. The mask 2 and the spacer material 201 are subsequently removed in further method steps known per se.

FIG. 11D illustrates in a plan view the two-dimensional structure after these method steps, in which the pads 200 are arranged on a substrate.

This embodiment can also be applied analogously to non-regular or differently formed two-dimensional patterns.

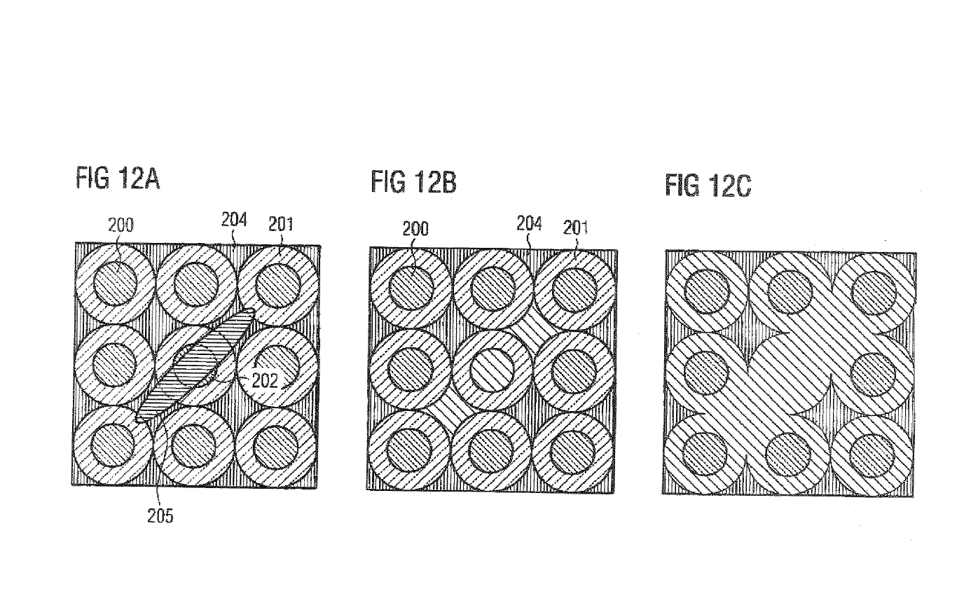

FIGS. 12A to 12C illustrate a further embodiment for the use of the method according to an embodiment of the invention. As in FIGS. 11A-11D, here as well a regular two-dimensional pattern is processed, although here produced by a sublithographic method.

FIG. 12A illustrates a plan view of such a pattern. The pattern shows an excerpt from a larger regular layout and in the example comprises nine round plugs 200 and filling regions 204 between the spacers, wherein the central plug 202 represents the structure which is intended to be etched away, i.e., removed from the pattern, together with the filling region 204 at the top on the right and at the bottom on the left. Each of the plugs 200 is surrounded by a ring-shaped spacer material 201 which can be etched selectively with respect to the material of the plug 200. The spacer material 201 forms the lateral etching stops 201. Filling material 204 is arranged in the interspaces between the plugs 200 surrounded by spacer material 201. A minimum distance between the plugs 200 is between 3 and 150 nm, and 70 nm is chosen here. The diameter of the plugs is 70 nm.

The entire two-dimensional structure is covered by a mask 2 (not illustrated in FIG. 12A) apart from the trimming opening 205 of the mask 2. The elliptical trimming opening 205 of the mask 2 partly covers the etching stops 201.

In an isotropic etching using the mask 2, the region below the trimming opening 205 is undercut, such that the filling material 204 and the material 200 to be etched are removed below the trimming opening 205.

Once the mask 2 has been removed, the situation illustrated in FIG. 12B has been produced. The regions 202 and from 204 below the elliptical trimming opening 205 have been etched away and only the etching stop 201 has remained in the center. The other plugs 200, the spacers 201 thereof and the rest of the filling material 204 remain.

In subsequent method steps, the etching stops 201 can then be removed in a targeted manner, such that only the plugs 200 and the filling material 204 remain.

The embodiment of the invention is not restricted to the preferred exemplary embodiments specified above. Rather, a number of variants are conceivable which make use of the method according to the invention and the structure according to the invention also in embodiments of fundamentally different configuration.

What is claimed is:

1. A method for forming an integrated circuit, the method comprising:
providing a structure that has at least one sublithographic partial structure wherein the at least one sublithographic partial structure has at least one structure to be etched with at least one lateral etch stop;
applying at least one mask in such a way that at least one lateral etch stop is covered by the mask;
etching at least one of the structures to be etched isotropically as far as at least one lateral etch stop using the mask; and
removing the at least one mask and removing the at least one etch stop.

2. The method as claimed in claim 1, wherein the at least one sublithographic partial structure has at least one line structure having a sublithographic width.

3. The method as claimed in claim 1, wherein the at least one lateral etch stop comprises a plurality of lateral etch stops produced by a sublithographic method, each lateral etch stop having an identical width.

4. The method as claimed in claim 1, wherein the at least one sublithographic partial structure has at least one line structure having a critical dimension that is less than 0.25*λ/NA or is less than a minimum half-pitch that can be achieved in practice by means of the exposure tool.

5. The method as claimed in claim 1, wherein the at least one sublithographic partial structure has a width between 10 nm and 100 nm.

6. The method as claimed in claim 1, wherein the at least one sublithographic partial structure has a plug structure having a minimum edge-to-edge distance of between 50 nm and 80 nm.

7. The method as claimed in claim 1, wherein the at least one lateral etch stop is a part of a layer deposited in a previous method step as a liner layer and/or spacer layer above the partial structure to be etched.

8. The method as claimed in claim 7, wherein the lateral etch stop has a thickness between 1 and 60 nm.

9. The method as claimed in claim 1, wherein the covering of the mask over the at least one lateral etch stop is at least 5 nm.

10. The method as claimed in claim 1, wherein etching isotropically is effected selectively with respect to the at least one lateral etch stop.

11. The method as claimed in claim 1, wherein the at least one lateral etch stop comprises nitride.

12. The method as claimed in claim 1, wherein removing the at least one lateral etch stop comprises performing an HF etch.

13. The method as claimed in claim 1, wherein etching at least one of the structures comprises a chloride etch.

14. The method as claimed in claim 1, wherein the mask is constructed in multilayer fashion.

15. The method as claimed in claim 14, wherein the mask comprises a resist layer, a BARC layer and/or a hard mask layer.

16. The method as claimed in claim 14, wherein the mask comprises a hard mask layer comprising SiON, Si₃N₄ and/or amorphous silicon.

17. The method as claimed in claim 1, further comprising performing an anisotropic incipient etch prior to the isotropic etching away of the at least one structure to be etched.

18. The method as claimed in claim 1, wherein etching isotropically of the at least one structure to be etched as far as at least one etch stop using the previously applied mask and the removal of the at least one mask and removal of the at least one etching stop lead to a self-aligned removal of the structure to be etched.

19. The method as claimed in claim 1, wherein the lithography for producing the structure is effected with a wavelength of 248 nm, 193 nm, 157 nm or 13.4 nm.

20. The method as claimed in claim 1, wherein the at least one partial structure to be etched and/or the at least one lateral etch stop have a regular pattern.

21. The method as claimed in claim 1, wherein forming an integrated circuit comprises forming a DRAM chip, an NROM chip or a microprocessor.

22. An integrated circuit that includes a structure wherein the structure has at least one sublithographic partial structure wherein the at least one sublithographic partial structure has at least one structure to be etched with at least one lateral etch stop that is part of a dielectric spacer structure, wherein the dielectric spacer structure electrically insulates parts of the at least one partial structure from one another.

23. The integrated circuit as claimed in claim 22, wherein the at least one lateral etch stop comprises an oxide and/or a nitride.

24. The integrated circuit as claimed in claim 22, wherein the lateral etch stop has a thickness between 10 and 60 nm.

25. The integrated circuit as claimed in claim 22, wherein the at least one lateral etch stop surrounds a line structure and/or a plug structure.

26. The integrated circuit as claimed in claim 22, wherein the integrated circuit comprises a DRAM chip, an NROM chip or a microprocessor or an intermediate product for a DRAM chip, an NROM chip or a microprocessor.
